(19) United States
(12) Patent Application Publication
(10) Pub. No.: US 2022/0310426 A1
(43) Pub. Date: Sep. 29, 2022

(54) MANUFACTURING-PROCESS DETECTION METHOD AND APPARATUS FOR WAFER AND ELECTRONIC DEVICE

(71) Applicant: CHANGXIN MEMORY TECHNOLOGIES, INC., Hefei City, Anhui Province (CN)

(72) Inventors: Panpan QIN, Hefei (CN); Wenying SHI, Hefei (CN)

(73) Assignee: CHANGXIN MEMORY TECHNOLOGIES, INC., Hefei City, Anhui Province (CN)

(21) Appl. No.: 17/439,773

(22) PCT Filed: Jun. 16, 2021
(86) PCT No.: PCT/CN2021/100454

§ 371 Date: Sep. 15, 2021

(30) Foreign Application Priority Data
Aug. 28, 2020 (CN) 202010884629.2

(51) Int. Cl. H01L 21/67; H01L 21/66

(52) U.S. Cl. CPC H01L 21/67253; H01L 22/30

(57) ABSTRACT

A manufacturing-process detection method and apparatus for a wafer, a medium and an electronic device are provided. The detection method includes: acquiring a first end time of manufacturing of the wafer in a first manufacturing chamber; acquiring a first start time of manufacturing of the wafer in a second manufacturing chamber, wherein the first manufacturing chamber and the second manufacturing chamber are manufacturing chambers in a same equipment; and detecting an actual waiting time of the wafer between the manufacturing chambers according to the first end time and the first start time.

### CROSS-REFERENCE TO RELATED APPLICATIONS

The present application is a national phase entry of International Patent Application No. PCT/CN2021/100454, filed on Jun. 16, 2021, which claims priority to Chinese Patent Application No. 202010884629.2, filed on Aug. 28, 2020. The aforementioned patent applications are incorporated herein by reference in their entirety.

### TECHNICAL FIELD

The present application relates to the field of semiconductor technologies, and in particular, to a manufacturing-process detection method and apparatus for a wafer and an electronic device.

### BACKGROUND

In a manufacturing process of semiconductor products such as wafers, a time difference monitoring system (Q-Time) in a Fault Detection and Classification (FDC) system can monitor a manufacturing time of a single manufacturing module and a time difference between different semiconductor manufacturing equipment.

In a related art, the time difference monitoring system cannot monitor an actual waiting time of a wafer elapsed between two manufacturing chambers. At the same time, with more than 100 manufacturing chambers and more than 40,000 processing steps per day, a semiconductor manufacturing equipment such as a coating developer cannot manually monitor the actual waiting time elapsed between the two manufacturing chambers Moreover, in the manufacturing process, the wafer is required to be processed after manufacturing chambers of a fixed type are paired in real time instead of being processed by fixed manufacturing chambers, which increases a difficulty of monitoring the actual waiting time.

How to monitor the actual waiting time of the wafer elapsed between the two manufacturing chambers to improve the quality of the wafer is an urgent technical problem to be solved currently.

### SUMMARY

According to a first aspect of the embodiments of the present application, a manufacturing-process detection method for a wafer is provided, including: acquiring a first end time of manufacturing of the wafer in a first manufacturing chamber; acquiring a first start time of manufacturing of the wafer in a second manufacturing chamber, wherein the first manufacturing chamber and the second manufacturing chamber are manufacturing chambers in a same equipment; and detecting an actual waiting time of the wafer between the manufacturing chambers according to the first end time and the first start time.

According to a second aspect of the embodiments of the present application, a manufacturing-process detection apparatus for a wafer is provided, including: an end-time acquisition unit configured to acquire a first end time of manufacturing of the wafer in a first manufacturing chamber; a start-time acquisition unit configured to acquire a first start time of manufacturing of the wafer in a second manufacturing chamber, wherein the first manufacturing chamber and the second manufacturing chamber are manufacturing chambers in a same equipment; and a detection unit configured to detect an actual waiting time of the wafer between the manufacturing chambers according to the first end time and the first start time.

According to a third aspect of the embodiments of the present application, an electronic device is provided, including: one or more processors; and a storage apparatus configured to store one or more programs, when the one or more programs are executed by the one or more processors, enabling the one or more processors to implement the manufacturing-process detection method for a wafer according to the first aspect in the above embodiment.

### BRIEF DESCRIPTION OF DRAWINGS

The accompanying drawings, which are incorporated herein and constitute a part of this specification, illustrate embodiments consistent with the present application and, together with the specification, serve to explain principles of the present application. It is apparent that, the accompanying drawings in the following description are only some embodiments of the present application, and other drawings can be obtained by those of ordinary skill in the art from the provided drawings without creative efforts. In the drawings,

FIG. 1 is a schematic diagram of calculation of a manufacturing time of a single manufacturing chamber in the related art;

FIG. 2 is a schematic diagram of calculation of a manufacturing time difference between manufacturing intervals of different equipment in the related art;

FIG. 3 is a flowchart of a manufacturing-process detection method for a wafer according to an embodiment of the present application;

FIG. 4 is a schematic diagram of a manufacturing-process detection method for a wafer according to another embodiment of the present application;

FIG. 5 is a schematic diagram of a univariate analysis curve according to an embodiment of the present application;

FIG. 6 is a block diagram of a manufacturing-process detection apparatus for a wafer according to another embodiment of the present application; and

FIG. 7 is a structural diagram of a computer system suitable for an electronic device configured to implement an embodiment of the present application.

### DESCRIPTION OF EMBODIMENTS

A more comprehensive description of exemplary implementations will now be given with reference to the drawings. However, the exemplary implementations may be implemented in a variety of forms but should not be construed as being limited to the examples described herein. Rather, these embodiments are provided to enable the present application to be more comprehensive and complete and the concept of the exemplary implementations to be fully conveyed to those skilled in the art. Same reference numerals in the drawings indicate same or similar structures, so their detailed description will be omitted.

Although relative terms such as “upper” and “lower” are used in the specification to describe a relative relationship of one component illustrated to another component, these terms are used in this specification for convenience only, for example, according to directions of examples described in the accompanying drawings. It will be understood that if the chamber illustrated is flipped upside down, the component described “above” will become the component “below”. Other relative terms such as “high”, “low”, “top”, “bottom”, “left” and “right” also have similar meanings. When a structure is “on” another structure, it is possible that a structure is integrally formed on another structure, or that a structure is “directly” disposed on another structure, or that a structure is “indirectly” disposed on another structure through other structures.

The terms “one”, “a/an”, and “the” are used to mean the presence of one or more elements/components, etc.; the terms “include/comprise” and “have” are used to mean an open inclusion and mean that there may be additional elements/components/etc. in addition to the listed elements/components/etc.

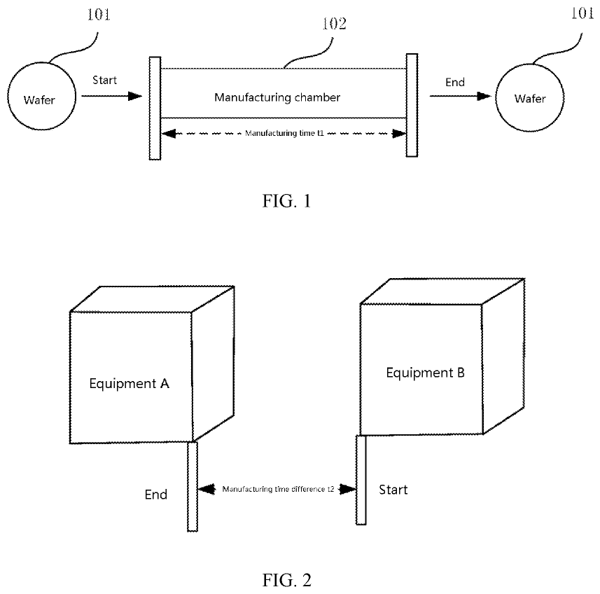

In the related art, a coating developer has functions of calculating a manufacturing time of a single manufacturing chamber and a cross-equipment manufacturing time difference. As shown in FIG. 1, the manufacturing time of the single manufacturing chamber refers to a manufacturing time t1 of a manufacturing chamber from the start of manufacturing to the end of manufacturing, which is limited to a manufacturing time of a monolithic wafer in the single manufacturing chamber. As shown in FIG. 2, the cross-equipment manufacturing time difference refers to a time elapsed from the end of manufacturing of one equipment to the start of manufacturing of next equipment, for example, a manufacturing time difference t2 between a equipment A and a equipment B.

However, the coating developer does not have a function of calculating an actual waiting time elapsed between manufacturing chambers. Specifically, a time difference monitoring system cannot monitor an actual waiting time of a wafer elapsed between two manufacturing chambers. At the same time, with more than 100 manufacturing chambers and more than 40,000 processing steps per day, it is difficult for a semiconductor manufacturing equipment such as a coating developer to manually monitor an actual waiting time actually elapsed between two manufacturing chambers so that the actual waiting time of the wafer elapsed between the two manufacturing chambers cannot be effectively monitored and the manufacturing quality of the wafer cannot be guaranteed.

In order to solve the above problem, the present application provides a manufacturing-process detection method and apparatus for a wafer, a computer-readable storage medium and an electronic device, so as to monitor an actual waiting time of the wafer elapsed between two manufacturing chambers and improve the manufacturing quality of the wafer.

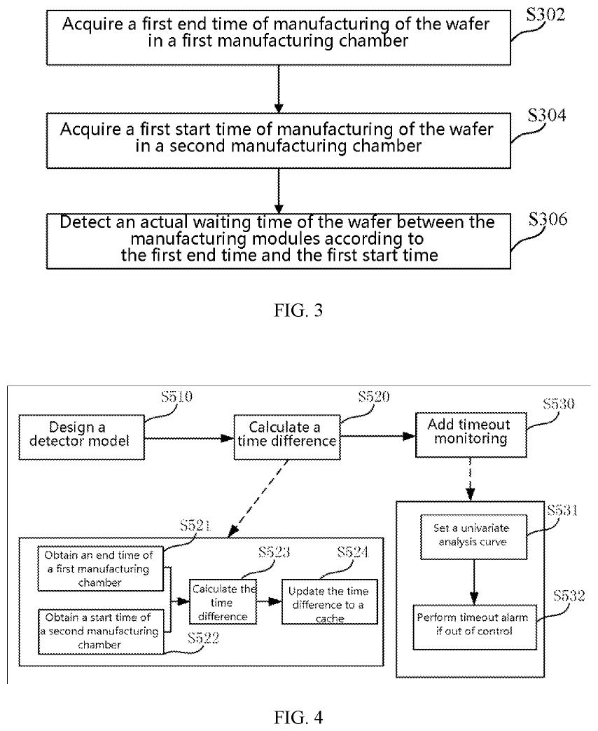

FIG. 3 is a flowchart of a manufacturing-process detection method for a wafer according to an embodiment of the present application. The method according to the embodiment of the present application may be performed by any electronic device with a computer processing capability, for example, a terminal device and/or a server. As shown in FIG. 3, an exemplary embodiment of the present application provides a manufacturing-process detection method for a wafer, including the following steps.

In step S302, a first end time of manufacturing of the wafer in a first manufacturing chamber is acquired.

In step S304, a first start time of manufacturing of the wafer in a second manufacturing chamber is acquired, wherein the first manufacturing chamber and the second manufacturing chamber are manufacturing chambers in a same equipment.

In step S306, an actual waiting time of the wafer between the manufacturing chambers is detected according to the first end time and the first start time.

In the embodiment of the present application, the manufacturing-process detection method for the wafer may be implemented by FDC (Fault Detection Classification). Through FDC, existing or potential faults of an equipment may be detected and analyzed by real-time detection of equipment-related parameters, which may directly acquire operation parameters of the equipment and plays an important role in monitoring safety and reliability of wafer products.

An actual waiting time elapsed between manufacturing intervals of two manufacturing chambers can be acquired by directly acquiring the operation parameters of the equipment, so as to monitor the manufacturing process of the wafer and improve the manufacturing quality of the wafer.

In the embodiment of the present application, the equipment may be a coating developer, and the first manufacturing chamber and the second manufacturing chamber may be manufacturing chambers in a coating process and a development process.

In addition, after step S306, a set waiting time, which is set in a system, of the wafer from the end of manufacturing in the first manufacturing chamber to the start of manufacturing in the second manufacturing chamber may also be acquired, and the manufacturing process of the wafer is monitored according to the set waiting time, the first end time and the first start time.

Specifically, after step S306, a time difference between the first end time and the first start time, that is, an actual waiting time, may be acquired, and it is determined, according to the time difference and the set waiting time, whether the manufacturing process times out.

Here, a procedure of the first manufacturing chamber may be previous to that of the second manufacturing chamber or may be N procedures prior to that of the second manufacturing chamber, where N is a natural number and greater than 1.

When the procedure of the first manufacturing chamber is N procedures prior to that of the second manufacturing chamber, other N−1 procedures exist between the procedure of the first manufacturing chamber and the procedure of the second manufacturing chamber.

During actual manufacturing, a delivery path of the wafer in internal manufacturing chambers of the coating developer is not fixed. According to idle states of the manufacturing chambers, the system randomly selects one of the manufacturing chambers of a same type to process the wafer.

The technical solution of the embodiment of the present application is flexible and practical, which may calculate a manufacturing time difference between manufacturing chambers of any specified coating developer. Moreover, the solution is not limited to the current equipment and may also be directly applied to subsequently deployed coating developers.

As shown in FIG. 4, in the embodiment of the present application, a detector model may be designed. The detector model includes a virtual detector, a wafer start chamber type parameter and an end chamber type parameter. The system detects an end time of the wafer at any specified first manufacturing chamber in the coating developer, and model timing begins. The system detects a start time of the wafer at any specified second manufacturing chamber in the coating developer, and the model timing ends. A time difference between a manufacturing end time of the first manufacturing chamber and a manufacturing start time of the second manufacturing chamber, that is, an actual waiting time, can be obtained by calculation according to the acquired end time of the first manufacturing chamber and start time of the second manufacturing chamber, and the time difference is updated to a cache of the virtual detector.

Specifically, as shown in FIG. 4, the manufacturing-process detection method for a wafer according to the embodiment of the present application includes the following steps.

In step S510, a detector model is designed.

In step S520, a time difference is calculated.

In step S530, timeout monitoring is added, and it is determined, according to a univariate analysis curve, whether the manufacturing process times out.

Specifically, step S520 includes the following steps.

In S521, an end time of a first manufacturing chamber is obtained.

In S522, a start time of a second manufacturing chamber is obtained.

In S523, the time difference is calculated.

In S524, the time difference is updated to a cache.

Specifically, step S530 includes the following steps.

In S531, the univariate analysis curve is set.

In S532, if it is out of control, timeout alarm is performed.

In this way, a time difference between internal manufacturing chambers is calculated by designing the virtual detector and combining programs, the value of the time difference is assigned to the designed virtual detector, and timeout monitoring is added.

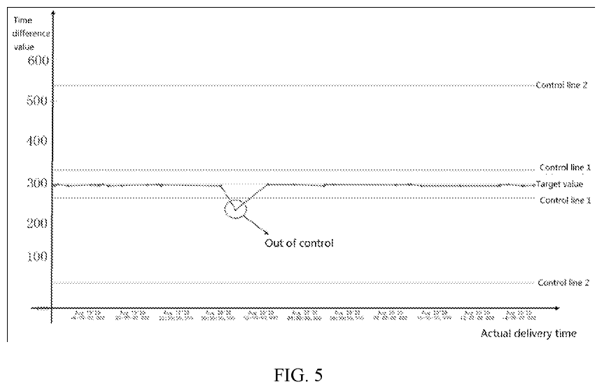

After step S306, it is determined, according to the time difference and the actual waiting time, whether the manufacturing process times out, and it is determined, according to the univariate analysis curve, whether the manufacturing process times out. Specifically, as shown in FIG. 5, a univariate analysis curve is set for the time difference by using a Univariate Analysis (UVA) algorithm.

As shown in FIG. 4 and FIG. 5, an alarm email or alarm information is generated for timeout alarm if the manufacturing process times out, i.e., out of control. As shown in FIG. 5, severity of a control line 2 is greater than that of a control line 1. If the value of the time difference exceeds the control line 2 and the control line 1, it is deemed to be out of control, and an alarm may be triggered.

In the technical solution according to the embodiment of the present application, a chamber type may be specified randomly, and a manufacturing time difference is dynamically calculated. The technical solution according to the embodiment of the present application may be applied to the field of integrated circuits and semiconductors, mainly involving FDC and a dynamic strategy chamber of an FDC system.

In the technical solution according to the embodiment of the present application, whether a manufacturing time of the wafer is abnormal can be monitored by calculating a time difference of manufacturing of a wafer product between different manufacturing chambers in the coating developer.

Detection analysis and monitoring are performed, by univariate analysis, on the time difference calculated, and the influence on the product quality caused by a too long manufacturing time of the wafer between internal chambers of the coating developer may be prevented.

In the manufacturing-process detection method for a wafer according to the embodiment of the present application, a first end time and a first start time are acquired, so that an actual waiting time of a wafer between two manufacturing chambers can be monitored, which improves the manufacturing quality of the wafer.

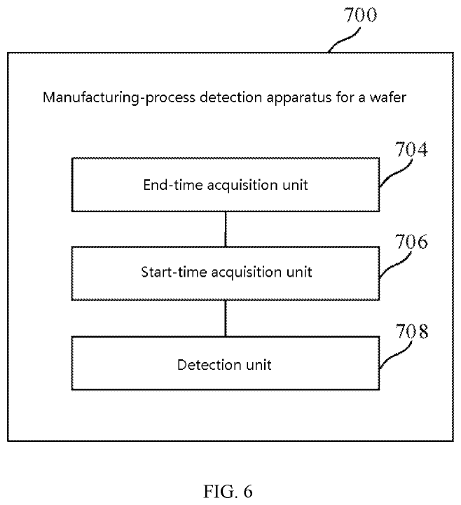

An apparatus embodiment of the present application is introduced below, which can be configured to perform the manufacturing-process detection method for a wafer according to the present application. As shown in FIG. 6, a manufacturing-process detection apparatus 700 for a wafer according to an embodiment of the present application may include:

an end-time acquisition unit 704 configured to acquire a first end time of manufacturing of the wafer in a first manufacturing chamber;

a start-time acquisition unit 706 configured to acquire a first start time of manufacturing of the wafer in a second manufacturing chamber, wherein the first manufacturing chamber and the second manufacturing chamber are manufacturing chambers in a same equipment; and

a detection unit 708 configured to detect an actual waiting time of the wafer between the manufacturing chambers according to the first end time and the first start time.

In addition, the detection apparatus 700 according to the embodiment of the present application may further include a set-waiting-time acquisition unit and a monitoring unit. The set-waiting-time acquisition unit is configured to acquire a set waiting time, which is set in a system, of the wafer from the end of manufacturing in the first manufacturing chamber to the start of manufacturing in the second manufacturing chamber. The monitoring unit is configured to monitor the manufacturing process of the wafer according to the set waiting time, the first end time and the first start time.

Since various functional chambers of the manufacturing-process detection apparatus for a wafer according to the exemplary embodiment of the present application correspond to the steps of the exemplary embodiment of the manufacturing-process detection method for a wafer, details not disclosed in the apparatus embodiment of the present application can be obtained with reference to the embodiment of the manufacturing-process detection method for a wafer according to the present application.

In the manufacturing-process detection apparatus for a wafer according to the embodiment of the present application, the first end time and the first start time are acquired, so that the actual waiting time of the wafer between the two manufacturing chambers can be monitored, which improves the manufacturing quality of the wafer.

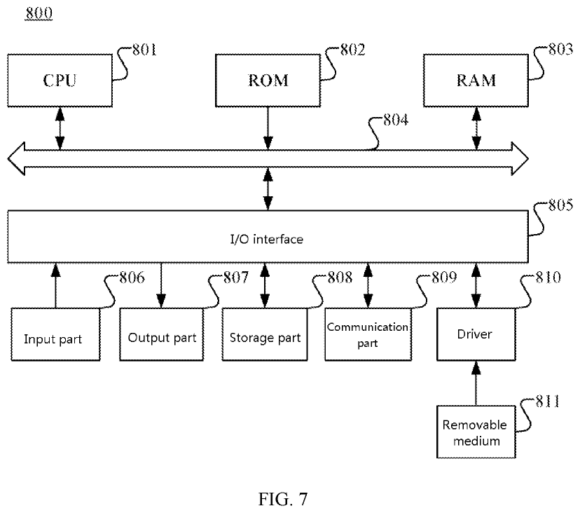

Refer to FIG. 7 below, which is a structural diagram of a computer system 800 suitable for an electronic device configured to implement an embodiment of the present application. The computer system 800 of the electronic device shown in FIG. 7 is an example only and should not impose any limitation on the functionality and scope of use of the embodiments of the present application.

As shown in FIG. 7, the computer system 800 includes a central processing unit (CPU) 801, which may perform various appropriate actions and processing according to a program stored in a read-only memory (ROM) 802 or a program loaded from a storage part 808 into a random access memory (RAM) 803. The RAM 803 may also store various programs and data required to operate the system. The CPU 801, the ROM 802 and the RAM 803 may be connected to each other by a bus 804. An input/output (I/O) interface 805 may also be connected to the bus 804.

The following components are connected to the I/O interface 805: an input part 806, such as a keyboard, a mouse, or the like; an output part 807, such as a cathode ray tube (CRT), a liquid crystal display (LCD), a speaker, or the like; a storage part 808, such as a hard disk; and a communication part 809, such as a network interface card, for example, a LANcard, a modem, or the like. The communication part 809 performs communication processing by using a network such as the Internet. A driver 810 may also be connected to the I/O interface 808 as required. A removable medium 811, such as a magnetic disk, an optical disc, a magneto-optical disk, or a semiconductor memory may be mounted on the driver 810 as required, so that a computer program read from the removable medium may be installed on the storage part 808 as required.

Particularly, according to an embodiment of the present application, the processes described above with reference to the flowchart may be implemented as computer software programs. For example, an embodiment of the present application provides a computer program product including a computer program hosted on a computer-readable storage medium. The computer program includes program codes configured to perform the method described in the flowchart. In such an embodiment, by using the communication part 809, the computer program may be downloaded and installed from a network and/or installed from the removable medium 811. The computer program, when executed by the central processing unit (CPU) 801, performs the above functions defined in the system of the present application.

It is to be noted that the computer-readable storage medium according to the present application may be a computer-readable signal medium or a computer-readable storage medium or any combination of the two. A computer-readable storage medium may be, for example, but is not limited to, an electronic, magnetic, optical, electromagnetic, infrared, or semiconductor system, apparatus, or device, or any combination thereof. More specific examples of the computer-readable storage medium may include, but are not limited to, an electrical connection having one or more wires, a portable computer diskette, a hard disk, a random access memory (RAM), a read-only memory (ROM), an erasable programmable read-only memory (EPROM or flash memory), an optical fiber, a portable compact disc read-only memory (CD-ROM), an optical storage device, a magnetic storage device, or any suitable combination thereof. In the present application, the computer-readable storage medium may be any tangible medium that may include or store a program for use by or in connection with an instruction execution system, apparatus, or device. In the present application, the computer-readable signal medium may include a data signal propagated in a baseband or as part of a carrier, which hosts computer-readable program codes. Such a propagated signal may be in a variety of forms, including, but not limited to, an electro-magnetic signal, an optical signal, or any suitable combination thereof. The computer-readable signal medium may be any other computer-readable storage medium than a computer-readable storage medium and that can communicate, propagate, or transport a program for use by or in connection with an instruction execution system, apparatus, or device. Program codes embodied on the computer-readable medium may be transmitted using any appropriate medium, including, but not limited to, wireless, wire, optical fiber cable, RF, etc., or any suitable combination thereof.

The flowcharts and block diagrams in the drawings show architectures, functions, and operations that may be implemented for the system, the method, and the computer program product according to various embodiments of the present application. In this regard, each block in a flowchart or a block diagram may represent a chamber, a program segment, or a part of codes. The chamber, the program segment, or the part of codes may include one or more executable instructions configured to implement specified logic functions. It is also to be noted that in some alternate implementations, the functions indicated in the boxes may also occur in a different order than those indicated in the drawings. For example, two blocks shown in succession may, in fact, be executed substantially concurrently, or the blocks may sometimes be executed in the reverse order, depending upon the functionality involved. It is also to be noted that each block of the block diagrams or flowcharts and a combination of blocks in the block diagrams or flowcharts can be implemented by special-purpose hardware-based systems that perform the specified functions or operations, or combinations of special-purpose hardware and computer instructions.

The units described in the embodiments of the present application may be implemented by software or by hardware, and the units described may also be arranged in a processor. The names of these units do not in some cases constitute a limitation on such units.

According to another aspect of the present application, the present application further provides a computer-readable storage medium. The computer-readable storage medium may be included in the electronic device described in the above embodiment, or a stand-alone computer-readable storage medium not assembled into the electronic device. The computer-readable storage medium hosts one or more programs. The one or more programs, when executed by an electronic device, enable the electronic device to implement the manufacturing-process detection method for a wafer according to the embodiment.

For example, the electronic device may implement the following steps shown in FIG. 3: step S302: acquiring the first end time of manufacturing of the wafer in the first manufacturing chamber; step S304: acquiring the first start time of manufacturing of the wafer in the second manufacturing chamber, wherein the first manufacturing chamber and the second manufacturing chamber are the manufacturing chambers in the same equipment; and step S306: detecting the actual waiting time of the wafer between the manufacturing chambers according to the first end time and the first start time.

For another example, the electronic device may also implement various steps shown in FIG. 4.

It is to be noted that, although several chambers or units of a device for action execution are mentioned in the foregoing detailed descriptions, the division is not mandatory. Actually, according to the implementations of the present disclosure, features and functions of the two or more chambers or units described above may be embodied in one chamber or unit. Conversely, the features and functions of one chamber or unit described above may be further divided into a plurality of chambers or units to be embodied.

Through the description of the foregoing embodiments, those skilled in the art can easily understand that the exemplary implementations described herein may be implemented by software, or may be implemented by combining software with necessary hardware. Therefore, the technical solutions of the implementations of the present application may be implemented in the form of a software product. The software product may be stored in a non-volatile storage medium (which may be a CD-ROM, a USB flash drive, a removable hard disk, or the like) or in a network and includes several instructions for instructing a computer device (which may be a personal computer, a server, a touch terminal, a network device, or the like) to perform the methods in the implementations of the present application.

Those skilled in the art can easily figure out another implementation solutions of the present application after considering the specification and practicing the application disclosed herein. The present application is intended to cover any variation, use, or adaptive change of the present application. These variations, uses, or adaptive changes follow the general principles of the present application and include common general knowledge or common technical means, which are not disclosed in the present application, in the technology. The specification and the embodiments are merely for an illustration purpose, and the true scope and spirit of the present application are subject to the following claims.

It should be understood that the present application is not limited to the exact construction that has been described above and illustrated in the accompanying drawings, and that various modifications and changes can be made without departing from the scope thereof. The scope of the present application is limited only by the appended claims.

1. A manufacturing-process detection method for a wafer, comprising:
acquiring a first end time of manufacturing of the wafer in a first manufacturing chamber;
acquiring a first start time of manufacturing of the wafer in a second manufacturing chamber, wherein the first manufacturing chamber and the second manufacturing chamber are manufacturing chambers in a same equipment; and
detecting an actual waiting time of the wafer between the manufacturing chambers according to the first end time and the first start time.

2. The detection method according to claim 1, further comprising:
acquiring a set waiting time, which is set in a system, of the wafer from the end of manufacturing in the first manufacturing chamber to the start of manufacturing in the second manufacturing chamber; and
monitoring the manufacturing process of the wafer according to the set waiting time, the first end time and the first start time.

3. The detection method according to claim 2, wherein the step of monitoring the manufacturing process of the wafer comprises:
acquiring a time difference between the first end time and the first start time; and
determining, according to the time difference and the set waiting time, whether the manufacturing process times out.

4. The detection method according to claim 1, wherein the equipment comprises a coating developer, and the first manufacturing chamber and the second manufacturing chamber comprise manufacturing chambers in a coating process and a development process.

5. The detection method according to claim 1, wherein a procedure of the first manufacturing chamber is previous to that of the second manufacturing chamber.

6. The detection method according to claim 1, wherein other procedures are comprised between the procedure of the first manufacturing chamber and the procedure of the second manufacturing chamber.

7. The detection method according to claim 3, wherein the step of determining, according to the time difference and the set waiting time, whether the manufacturing process times out comprises:
determining, according to a univariate analysis curve, whether the manufacturing process times out.

8. The detection method according to claim 7, wherein after the step of determining, according to the time difference and the set waiting time, whether the manufacturing process times out, the method further comprises:
generating an alarm email or alarm information for timeout alarm if the manufacturing process times out.

9. A manufacturing-process detection apparatus for a wafer, comprising:
an end-time acquisition unit configured to acquire a first end time of manufacturing of the wafer in a first manufacturing chamber;
a start-time acquisition unit configured to acquire a first start time of manufacturing of the wafer in a second manufacturing chamber, wherein the first manufacturing chamber and the second manufacturing chamber are manufacturing chambers in a same equipment; and
a detection unit configured to detect an actual waiting time of the wafer between the manufacturing chambers according to the first end time and the first start time.

10. The detection apparatus according to claim 9, further comprising:
a set-waiting-time acquisition unit configured to acquire a set waiting time, which is set in a system, of the wafer from the end of manufacturing in the first manufacturing chamber to the start of manufacturing in the second manufacturing chamber; and
a monitoring unit configured to monitor the manufacturing process of the wafer according to the set waiting time, the first end time and the first start time.

11. An electronic device, comprising:
one or more processors; and
a storage apparatus configured to store one or more programs, when the one or more programs are executed by the one or more processors, enabling the one or more processors to implement the manufacturing-process detection method for a wafer according to claim 1.
